(19) United States
(12) Patent Application Publication
(10) Pub. No.: US 2021/0311389 A1
(43) Pub. Date: Oct. 7, 2021

(54) RESIN COMPOSITION FOR RESISTS AND USE THEREOF

(71) Applicant: ARISAWA MFG. CO., LTD., Joetsu-shi, Niigata (JP)

(72) Inventors: Takashi GONDAIRA, Joetsu-shi, Niigata (JP); Akira ISHIDA, Joetsu-shi, Niigata (JP)

(21) Appl. No.: 17/263,780

(22) PCT Filed: Jun. 28, 2019
(86) PCT No.: PCT/JP2019/025900

§ 371 Date: Jan. 27, 2021

(30) Foreign Application Priority Data
Aug. 1, 2018 (JP) 2018-145361

(51) Int. Cl. G03F 7/028; H05K 3/06; C08L 33/10; C08F 2/50; G03F 7/038

(52) U.S. Cl. CPC G03F 7/028; H05K 3/064; C08L 2203/202; C08F 2/50; G03F 7/038; C08L 33/10

(57) ABSTRACT

The present invention provides a resin composition for resists that is for obtaining a resist which has the characteristics conventionally required of a resist and which also does not generate warping. This resin composition for resists includes a (meth)acrylic photocurable polymer, a thermosetting agent, and a photopolymerization initiator. The (meth)acrylic photocurable polymer includes a carboxyl group, an open-chain aliphatic hydrocarbon group having 12 or more carbon atoms, and an unsaturated double bond, and the glass transition temperature (Tg) of the (meth)acrylic photocurable polymer is 20° C. or less.

### TECHNICAL FIELD

The present invention relates to a resin composition for resists and uses thereof, and more particularly to a resin composition for resists having photopolymerizability, cured by energy ray irradiation, a cured product using the resin composition for resists, a solder resist film, a circuit board, a substrate for a semiconductor package, and an electronic device.

### BACKGROUND ART

When surface processing such as physical treatment such as sand blasting or chemical treatment such as etching is performed to a surface of an object, a film is formed on a part of the surface, thereby protecting the surface. The formed protective film and a covering material for forming the protective film are referred to as a resist, and the resist is mainly used for a printed board for an electronic component, a semiconductor package, or the like. The resist is classified into a solder resist, a photoresist, a screen printing resist, an etching resist, a plating resist, or the like depending on a forming method or a use of the protective film.

For example, a solder resist is used for a package board (substrate for packages) of a semiconductor package, and the package board has a structure in which wiring layers (build-up layers) are laminated above and below a core layer which is a support, and a solder resist is piled up on parts of outermost layers where soldering is not required.

The solder resist needs to have a function of protecting a surface of the object as described above, and characteristics such as developability, chemical resistance, photocurability, heat resistance, adhesion, and electrical insulation properties are required. Further, various studies have been made in the related art on a photosensitive resin composition used in the solder resist.

For example, Patent Literature 1 proposes a photosensitive thermosetting resin composition containing: a photocurable compound (A) obtained by reacting a polybasic acid anhydride (d) with an reaction product obtained by reacting an epoxy compound (a) having three or more epoxy groups in one molecule with an unsaturated monocarboxylic acid (b) and a saturated monocarboxylic acid (c); an epoxy compound (B) having two or more epoxy groups in one molecule: a photopolymerization initiator (C); and a diluent (D) as essential components. Patent Literature 2 proposes a photosensitive resin composition containing: (A) a binder polymer; (B) a photopolymerizable compound having an ethylenically unsaturated bond; (C) a photopolymerization initiator; and (D) a thermal curing agent, wherein the component (B) includes a photopolymerizable compound having a fluorene skeleton and an oxyethylene group or oxypropylene group in a molecule (B-1).

### CITATION LIST

### Patent Literature

Patent Literature 1: JP-A-2004-137328
Patent Literature 2: JP-A-2010-160418

### SUMMARY OF INVENTION

### Technical Problem

Along with recent reduction in thickness, size, cost, and the like of electrical equipment, space in a case for accommodating components tends to be limited, and it is desired to reduce thickness of a package board even in a semiconductor package. As a countermeasure thereof, film thinning of a core layer or use of a coreless board, one side mounting of a solder resist on a package board, and the like are performed.

When a front side (one face) and a back side (the other face) are asymmetrical in a cross section of a board, warpage easily occurs in the board. In a case where the solder resist is applied or stuck to only one side, warpage is significant. In addition, since parts on a front side where soldering is not required do not necessarily correspond to those on a back side of the package board, the front side and the back side become asymmetrical even if the solder resists are provided on both sides. Thus, warpage may occur in the board when the core layer is thinned or is to be formed into the coreless board.

Therefore, an object of the present invention is to provide a resin composition for resists for obtaining a board which does not warp while having characteristics of a resist required in the related art.

### Solution to Problem

As a result of intensive studies to solve the above problem, the present inventors have found that the above problem can be solved by using a (meth)acrylic photocurable polymer containing a chain aliphatic hydrocarbon group having 12 or more carbon atoms and having a glass transition temperature (Tg) of 20° C. or lower as a photopolymerizable compound to complete the present invention.

That is, the present invention includes the following (1) to (15).

(1) A resin composition for resists containing: a (meth)acrylic photocurable polymer; a thermal curing agent; and a photopolymerization initiator, wherein the (meth)acrylic photocurable polymer contains a carboxyl group, a chain aliphatic hydrocarbon group having 12 or more carbon atoms, and an unsaturated double bond, and the (meth)acrylic photocurable polymer has a glass transition temperature (Tg) of 20° C. or lower.
(2) The resin composition for resists according to the above (1), wherein the (meth)acrylic photocurable polymer is an addition copolymer obtained by reacting a reactive compound containing an ethylenically unsaturated double bond with a (meth)acrylic copolymer obtained by copolymerizing at least a (meth)acrylic polymerizable compound containing a carboxyl group and a polymerizable compound containing a chain aliphatic hydrocarbon group.
(3) The resin composition for resists according to the above (2), wherein the polymerizable compound containing a chain aliphatic hydrocarbon group is an alkyl (meth)acrylate having 12 to 24 carbon atoms.
(4) The resin composition for resists according to the above (2) or (3), wherein a content of a segment derived from the polymerizable compound containing a chain aliphatic hydrocarbon group in the (meth)acrylic photocurable polymer is in a range of 10 mass % to 50 mass %.
(5) The resin composition for resists according to any one of the above (1) to (4), wherein the (meth)acrylic photocurable polymer has an acid value of 50 mg KOH/g to 100 mg KOH/g.
(6) The resin composition for resists according to any one of the above (1) to (5), wherein the (meth)acrylic photocurable polymer has a double bond equivalent of 300 g/eq to 1000 g/eq.
(7) The resin composition for resists according to any one of the above (1) to (6), wherein a cured product obtained by curing the resin composition for resists has a glass transition temperature (Tg) of 100° C. or lower.
(8) The resin composition for resists according to any one of the above (1) to (7), further containing a photopolymerizable compound other than the (meth)acrylic photocurable polymer.
(9) The resin composition for resists according to any one of the above (1) to (8), which is for a solder resist.
(10) The resin composition for resists according to any one of the above (1) to (9), which is for a semiconductor package.
(11) A cured product obtained by curing the resin composition for resists according to any one of the above (1) to (10).
(12) A solder resist film containing the resin composition for resists according to any one of the above (1) to (10).
(13) A circuit board containing the solder resist film according to the above (12).
(14) A substrate for a semiconductor package containing the solder resist film according to the above (12).
(15) An electronic device containing the circuit board according to the above (13) or the substrate for a semiconductor package according to the above (14).

### Advantageous Effects of Invention

According to the resin composition for resists of the present invention, since the specific (meth)acrylic photocurable polymer is contained, characteristics required for the resist, particularly chemical resistance is provided, and warpage of a cured film can be reduced. Therefore, an electronic device that can be suitably used in a thin package board or the like and has high quality reliability can be obtained.

### DESCRIPTION OF EMBODIMENTS

Although embodiments of the present invention will be described in detail, the present invention is not limited to the following embodiments, and various modifications can be carried out within the scope of the gist thereof.

In the present invention, “(meth)acryl” means acryl or methacryl, and the same applies to (meth)acrylate. In addition, “(iso)” means both a case where this group is present and a case where this group is not present, and the case where this group is not present means normal.

Further, in the present description, “mass” has the same meaning as “weight”.

The resin composition for resists of the present invention contains at least a (meth)acrylic photocurable polymer, a thermal curing agent, and a photopolymerization initiator. Each component will be described below.

### <(Meth)Acrylic Photocurable Polymer>

The (meth)acrylic photocurable polymer used in the present embodiment contains a carboxyl group, a chain aliphatic hydrocarbon group having 12 or more carbon atoms, and an unsaturated double bond, and has a glass transition temperature (Tg) of 20° C. or lower.

Since the (meth)acrylic photocurable polymer has a photocurable unsaturated double bond, the resin composition for resists of the present invention is polymerized by irradiation with light energy rays such as ultraviolet rays in the presence of the photopolymerization initiator to form a cured product. Further, since the (meth)acrylic photocurable polymer has a carboxyl group, development with a developer such as a dilute alkaline aqueous solution is possible. Since the glass transition temperature (Tg) of the (meth)acrylic photocurable polymer is 20° C. or lower, the cured product obtained by curing the resin composition for resists of the present invention has appropriate flexibility. The chain aliphatic hydrocarbon group having 12 or more carbon atoms in the (meth)acrylic photocurable polymer can impart hydrophobicity to the (meth)acrylic photocurable polymer, thereby improving chemical resistance to a water-soluble chemical liquid. The unsaturated double bond is distinguished from a double bond in the carboxyl group.

The (meth)acrylic photocurable polymer of the present embodiment is an addition copolymer obtained by adding a compound having an unsaturated double bond to a (meth) acrylic copolymer. The (meth)acrylic photocurable polymer can be produced, for example, by reacting a reactive compound (d) containing an ethylenically unsaturated double bond with a (meth)acrylic copolymer (X) obtained by copolymerizing at least a (meth)acrylic polymerizable compound (a) containing a carboxyl group and a polymerizable compound (b) containing a chain aliphatic hydrocarbon group.

The (meth)acrylic polymerizable compound (a) containing a carboxyl group is a (meth)acrylic monomer which contains a carboxyl group in its molecule and can be copolymerized with another polymerizable compound.

Examples of the (meth)acrylic polymerizable compound (a) containing a carboxyl group include unsaturated monocarboxylic acids such as (meth)acrylic acid, 2-acryloyloxyethyl succinate, 2-(meth)acryloyloxyethyl-succinic acid, 2-acryloyloxyethyl hexahydrophthalic acid, 2-acryloyloxyethyl-phthalic acid, and 2-acryloyloxyethyl-2-hydroethyl-phthalic acid. One of these may be used alone, or two or more of these may be used in combination. Among them, (meth)acrylic acid is more preferable in view of versatility.

The chain aliphatic hydrocarbon group-containing polymerizable compound (b) is a monomer which contains a chain aliphatic hydrocarbon group in its molecule and can be copolymerized with another polymerizable compound.

The chain aliphatic hydrocarbon group may be linear or branched. The chain aliphatic hydrocarbon group has 12 or more carbon atoms, preferably 12 to 24 carbon atoms, and more preferably 16 to 24 carbon atoms. When the number of carbon atoms of the chain aliphatic hydrocarbon group is 12 or more, hydrophobicity to the (meth)acrylic photocurable polymer can be imparted, thereby improving chemical resistance to a water-soluble chemical liquid.

Examples of the polymerizable compound (b) containing a chain aliphatic hydrocarbon group include an alkyl (meth)acrylate having 12 to 24 carbon atoms. Examples of the alkyl (meth)acrylate having 12 to 24 carbon atoms include lauryl (meth)acrylate, cetyl (meth)acrylate, (iso)stearyl (meth)acrylate, and behenyl (meth)acrylate. One of these may be used alone, or two or more of these may be used in combination. Among them, (iso)stearyl (meth)acrylate is more preferable.

At least the (meth)acrylic polymerizable compound (a) containing a carboxyl group and the polymerizable compound (b) containing a chain aliphatic hydrocarbon group can be copolymerized to obtain the (meth)acrylic copolymer (X). In order to adjust the glass transition temperature (Tg), an elastic modulus, and heat resistance of the (meth)acrylic photocurable polymer which is a final object, it is preferable to further use the other polymerizable compound (c) (monomer) other than the polymerizable compounds (a) and (b), which is copolymerizable with the (meth)acrylic polymerizable compound (a) containing a carboxyl group and the polymerizable compound (b) containing a chain aliphatic hydrocarbon group.

Examples of the other polymerizable compound (c) can include aromatic vinyl compounds such as styrene, α-methyl styrene, o-vinyl toluene, m-vinyl toluene, p-vinyl toluene, p-chloro styrene, o-methoxy styrene, m-methoxy styrene, p-methoxy styrene, o-vinyl benzyl methyl ether, m-vinyl benzyl methyl ether, p-vinyl benzyl methyl ether, o-vinyl benzyl glycidyl ether, m-vinyl benzyl glycidyl ether, and p-vinyl benzyl glycidyl ether; and unsaturated carboxylic acid esters such as methyl (meth)acrylate, ethyl (meth)acrylate, n-propyl (meth)acrylate, i-propyl (meth)acrylate, n-butyl (meth)acrylate, i-butyl (meth)acrylate, sec-butyl (meth)acrylate, t-butyl (meth)acrylate, 2-hydroxyethyl (meth)acrylate, 2-hydroxypropyl (meth)acrylate, 3-hydroxypropyl (meth)acrylate, 2-hydroxybutyl (meth)acrylate, 3-hydroxybutyl (meth)acrylate, 4-hydroxybutyl (meth)acrylate, allyl (meth)acrylate, benzyl (meth)acrylate, cyclohexyl (meth)acrylate, phenyl (meth)acrylate, 2-methoxyethyl (meth)acrylate, 2-phenoxyethyl (meth)acrylate, methoxy diethylene glycol (meth)acrylate, methoxy triethylene glycol (meth)acrylate, methoxy propylene glycol (meth)acrylate, methoxy dipropylene glycol (meth)acrylate, isobornyl (meth)acrylate, dicyclopentadienyl (meth)acrylate, norbornyl (meth)acrylate, 2-hydroxy-3-phenoxypropyl (meth)acrylate, and glycerol mono (meth)acrylate. One of these may be used alone, or two or more of these may be used in combination. Among them, styrene and n-butyl (meth)acrylate are preferably used.

The (meth)acrylic polymerizable compound (a) containing a carboxyl group is preferably combined so that an acid value of the (meth) acrylic photocurable polymer which is the final object is 50 mg KOH/g to 100 mg KOH/g.

The polymerizable compound (b) containing a chain aliphatic hydrocarbon group is preferably combined so that a content of a segment derived from the polymerizable compound (b) containing a chain aliphatic hydrocarbon group in the (meth)acrylic photocurable polymer which is the final object is 10 mass % to 50 mass %.

A combination amount of the other polymerizable compound (c) is a difference obtained by subtracting total mass % of the (meth)acrylic polymerizable compound (a) containing a carboxyl group, the polymerizable compound (b) containing a chain aliphatic hydrocarbon group, and the reactive compound (d) containing an ethylenically unsaturated double bond from 100 mass % when the (meth)acrylic photocurable polymer which is the final object is 100 mass %. The other polymerizable compound (c) is preferably a compound selected such that the glass transition temperature (Tg) of the (meth)acrylic photocurable polymer is 20° C. or lower.

The (meth)acrylic copolymer (X) is obtained by mixing the (meth)acrylic polymerizable compound (a) containing a carboxyl group and the polymerizable compound (b) containing a chain aliphatic hydrocarbon group, and the other polymerizable compound (c) as desired, and reacting at a reaction temperature of 80° C. to 130° C., preferably 100° C. to 120° C. for 5 to 10 hours, preferably 6 to 8 hours.

When the resin composition for resists of the present invention is cured to obtain a cured product, a thermal polymerization initiator, a solvent for polymerization, a chain transfer agent, and the like may be combined in the reaction as long as they does not impair characteristics of the cured product.

Examples of the thermal polymerization initiator include azo compounds such as 2,2-azobisisobutyronitrile (AIBN), 2,2′-azobis(2-methyl butyronitrile) (AMBN), azobiscyanovaleric acid, 2,2′-azobis(4-methoxy-2,4-dimethyl valeronitrile), 2,2′-azobis(2,4-dimethyl valeronitrile), dimethyl 2,2′-azobis(2-methyl propionate), 2,2′-azobis(2-methyl butyronitrile), 1,1′-azobis(cyclohexane-1-carbonitrile), 2,2′-azobis[N-(2-propenyl)-2-methyl propionamide], 2,2′-azobis(N-butyl-2-methyl propionamide), 2,2′-azobis[2-(2-imidazoline-2-yl) propane] dihydrochloride, 2,2′-azobis[2-(2-imidazoline-2-yl) propane] disulfate dihydrate, 2,2′-azobis(2-methyl propionamidine) dihydrochloride, 2,2′-azobis[N-(2-carboxyethyl)-2-methyl propionamidine] hydrate, 2,2′-azobis[2-(2-imidazoline-2-yl) propane], 2,2′-azobis(1-imino-1-pyrrolidino-2-methyl propane) dihydrochloride, 2,2′-azobis[2-methyl-N-(2-hydroxyethyl) propionamide]; and organic peroxides such as tert-butyl peroxypivalate, tert-butyl peroxybenzoate, tert-butyl peroxy-2-ethyl hexanoate, di-tert-butyl peroxide, cumene hydroperoxide, benzoyl peroxide, and tert-butyl hydroperoxide. One of these may be used alone, or two or more of these may be used in combination.

An addition amount of the thermal polymerization initiator is preferably 0.5 mass % to 30 mass %, more preferably 1 mass % to 20 mass %, and even more preferably 10 mass % to mass % with respect to a total mass of monomers to be copolymerized. The thermal polymerization initiator may be added at one time, or may be added in several times.

The solvent for polymerization is not particularly limited as long as it can dissolve the monomers to be polymerized, a polymer precursor to be generated, and a polymerization initiator or other additives if necessary. As the solvent for polymerization, methanol, ethanol, isopropanol, tetrahydrofuran, cyclohexanone, methyl ethyl ketone, ethylene glycol monomethyl ether, ethylene glycol monoethyl ether, 2-methoxy ethyl acetate, diethylene glycol dimethyl ether, 1-methoxy-2-propanol, 1-methoxy-2-propyl acetate, N,N-dimethyl formamide, N,N-dimethyl acetamide, toluene, ethyl acetate, ethyl lactate, methyl lactate, dimethyl sulfoxy, and the like can be used. One of these may be used alone, or two or more of these may be used in combination.

Examples of the chain transfer agent include mercaptans such as methyl mercaptan, t-butyl mercaptan, decyl mercaptan, benzyl mercaptan, lauryl mercaptan, stearyl mercaptan, n-dodecyl mercaptan, t-dodecyl mercaptan, mercapto acetic acid, mercapto propionic acid and esters thereof, 2-ethyl hexyl thioglycol, octyl thioglycolate; alcohols such as methanol, ethanol, propanol, n-butanol, isopropanol, t-butanol, hexanol, benzyl alcohol, and allyl alcohol; halogenated hydrocarbons such as chloroethane, fluoroethane, and trichloroethylene; carbonyls such as acetone, methyl ethyl ketone, cyclohexanone, acetophenone, acetaldehyde, propionaldehyde, n-butylaldehyde, furfural, and benzaldehyde; and methyl-4-cyclohexene-1,2-dicarboxylic acid anhydride, α-methyl styrene, and α-methyl styrene dimer. One of these may be used alone, or two or more of these may be used in combination.

The reactive compound (d) containing an ethylenically unsaturated double bond is a monomer capable of reacting with the (meth)acrylic copolymer (X) to introduce a group having an unsaturated double bond into the copolymer. Examples of the reactive compound (d) containing an ethylenically unsaturated double bond include a monomer that has a group having an ethylenically unsaturated double bond and a reactive group such as an epoxy group (cyclic ether) or a hydroxy group in the molecule.

A reactive compound (d1) containing an ethylenically unsaturated double bond and having an epoxy group (cyclic ether) is added to the (meth)acrylic copolymer (X) by a condensation reaction (esterification reaction) between a hydroxy group generated by opening the cyclic ether and a carboxyl group of the (meth)acrylic copolymer (X).

Examples of the reactive compound (d1) containing an ethylenically unsaturated double bond and having an epoxy group include glycidyl (meth)acrylate and 3,4-epoxy cyclohexyl (meth)acrylate. One of these may be used alone, or two or more of these may be used in combination. In particular, glycidyl methacrylate is preferable in view of versatility.

A reactive compound (d2) containing an ethylenically unsaturated double bond and having a hydroxy group is added to the (meth)acrylic copolymer (X) by a condensation reaction (esterification reaction) between the hydroxy group and a carboxyl group of the (meth)acrylic copolymer (X).

Examples of the reactive compound (d2) containing an ethylenically unsaturated double bond and having a hydroxy group include 2-hydroxyethyl (meth)acrylate, 2-hydroxypropyl (meth)acrylate, 2-hydroxybutyl (meth)acrylate, and 2-hydroxy-3-phenoxypropyl (meth)acrylate. One of these may be used alone, or two or more of these may be used in combination. Among them, 2-hydroxyethyl (meth)acrylate is preferable in view of versatility.

The reactive compound (d) containing an ethylenically unsaturated double bond is preferably combined so that a double bond equivalent of the (meth)acrylic photocurable polymer which is the final object is 300 g/eq to 1000 g/eq.

In an addition reaction of the reactive compound (d) containing an ethylenically unsaturated double bond to the (meth)acrylic copolymer (X), the carboxyl group of the (meth)acrylic copolymer (X) reacts with a reactive group of the reactive compound (d) containing an ethylenically unsaturated double bond. However, a polymerization reaction of a (meth)acrylate part of the reactive compound (d) containing an ethylenically unsaturated double bond may proceed in a nitrogen atmosphere, for example. Therefore, the addition reaction of the reactive compound (d) containing an ethylenically unsaturated double bond to the (meth)acrylic copolymer (X) is preferably performed in an air atmosphere in view of reducing proceeding of the polymerization reaction.

The (meth)acrylic photocurable polymer is obtained by mixing the (meth)acrylic copolymer (X) and the reactive compound (d) containing an ethylenically unsaturated double bond and reacting them at a reaction temperature of 90° C. to 120° C., preferably 100° C. to 110° C. for 5 to 30 hours, preferably 10 to 20 hours.

A reaction accelerator, a solvent, a polymerization inhibitor, and the like may be mixed in the reaction.

Examples of the reaction accelerator can include benzyldimethylamine, triethanolamine, triethylenediamine, dimethylaminoethanol, tri(dimethylaminomethyl) phenol, 2-methyl imidazole, 2-phenyl imidazole, triphenylphosphine, diphenylphosphine, phenylphosphine, tetraphenylphosphonium tetraphenylborate, and triphenylphosphine tetraphenylborate. Among them, triphenylphosphine is preferable in view of stability. One of these reaction accelerators may be used alone, or two or more thereof may be used in combination.

As the solvent, there is no particular limit, and methanol, ethanol, isopropanol, tetrahydrofuran, cyclohexanone, methyl ethyl ketone, ethylene glycol monomethyl ether, ethylene glycol monoethyl ether, 2-methoxy ethyl acetate, diethylene glycol dimethyl ether, 1-methoxy-2-propanol, 1-methoxy-2-propyl acetate, N,N-dimethyl formamide, N,N-dimethyl acetamide, toluene, ethyl acetate, ethyl lactate, methyl lactate, dimethyl sulfoxide, and the like can be used. One of these may be used alone, or two or more of these may be used in combination.

Examples of the polymerization inhibitor include phenothiazine, tri-p-nitrophenyl methyl, di-p-fluorophenylamine, diphenyl picryl hydrazyl, N-(3-N-oxyanilino-1,3-dimethyl butylidene) aniline oxide, benzoquinone, hydroquinone, methoquinone, butylcatechol, nitrosobenzene, picric acid, dithiobenzoyl disulfide, cupferron, and copper (II) chloride. Among them, methoquinone is preferably used in view of a polymerization inhibition effect. One of these polymerization inhibitors may be used alone, or two or more thereof may be used in combination.

In the present embodiment, a content of the segment derived from the polymerizable compound (b) containing a chain aliphatic hydrocarbon group in the (meth)acrylic photocurable polymer is preferably 10 mass % to 50 mass %. When the content of the segment derived from the polymerizable compound (b) containing a chain aliphatic hydrocarbon group is 10 mass % or more, chemical resistance to water-soluble chemical liquid can be improved since hydrophobicity can be imparted to the (meth)acrylic photocurable polymer. When the content of the segment is 50 mass % or less, the (meth)acrylic photocurable polymer does not become too hydrophobic and does not adversely affect developability. The content of the segment derived from the polymerizable compound (b) containing a chain aliphatic hydrocarbon group is more preferably 10 mass % to 40 mass %, and still more preferably 20 mass % to 30 mass %.

The content of the segment derived from the polymerizable compound (b) containing a chain aliphatic hydrocarbon group in the acrylic photocurable polymer can be determined by calculation from a content ratio of the monomer components used for synthesis.

In the present embodiment, an acrylic acrylate containing an acid group copolymerized with an isostearyl acrylate ((meth)acrylic photocurable polymer) can be obtained by using, for example: acrylic acid as the (meth)acrylic polymerizable compound (a) containing a carboxyl group; isostearyl acrylate as the polymerizable compound (b) containing a chain aliphatic hydrocarbon group; butyl acrylate and styrene as the other polymerizable compounds (c); and glycidyl methacrylate as the reactive compound (d) containing an ethylenically unsaturated double bond.

Specifically, first, acrylic acid, isostearyl acrylate, butyl acrylate, and styrene are mixed at an arbitrary combination ratio within the above ranges and reacted to obtain a copolymer. The obtained copolymer and glycidyl methacrylate are mixed at an arbitrary combination ratio in the above-described range and react to open a cyclic ether in glycidyl methacrylate, which is subjected to an addition reaction with a part of the carboxyl group in the segment derived from acrylic acid in the copolymer, in which glycidyl methacrylate is added to the copolymer by an esterification reaction to obtain an acrylic acrylate containing an acid group copolymerized with an isostearyl acrylate (addition copolymer).

In the present embodiment, the glass transition temperature (Tg) of the (meth)acrylic photocurable polymer is 20° C. or lower. When the Tg is 20° C. or lower, an elongation percentage of the cured product increases, and flexibility is imparted to the cured product, so that warpage can be reduced. The Tg is preferably 10° C. or lower, and more preferably 5° C. or lower. A lower limit thereof is not particularly limited, but since a film before curing formed of the resin composition for resists of the present invention may have strong tack (stickiness) and may be difficult to handle when the Tg is too low, the Tg is preferably −20° C. or higher, and more preferably −10° C. or higher. The Tg of the (meth)acrylic photocurable polymer can be adjusted by, for example, adjusting the combination ratio of the components, chemical structures of the components, and a crosslinking degree of the polymer when the (meth)acrylic copolymer (X) is obtained. As for the glass transition temperature (Tg), the Tg may be measured by thermal analysis of the (meth)acrylic photocurable polymer, or may simply use a value that can be determined as a theoretical value by calculation from the glass transition temperature of each monomer component used in the synthesis. When Tg (theoretical Tg) is determined by the theoretical value, the Tg can be calculated by a FOX formula.

In the present embodiment, an acid value of the (meth)acrylic photocurable polymer is preferably 50 mg KOH/g to 100 mg KOH/g. The acid value is preferably 50 mg KOH/g or more since development can be performed in a short time, and is preferably 100 mg KOH/g or less since there is little curing shrinkage.

The acid value can be measured based on a method described in JIS K0070.

In the present embodiment, a double bond equivalent of the (meth)acrylic photocurable polymer is preferably 300 g/eq to 1000 g/eq. The double bond equivalent is preferably 300 g/eq or more since an influence of curing shrinkage can be reduced, and the double bond equivalent is preferably 1000 g/eq or less since the double bonds can sufficiently react by irradiation with light energy rays to obtain excellent resolution.

In the present embodiment, a weight average molecular weight (Mw) of the (meth)acrylic photocurable polymer is preferably 10,000 mg KOH/g to 50,000 mg KOH/g. The weight average molecular weight (Mw) is preferably 10,000 or more since film properties after curing are good, and the weight average molecular weight (Mw) is preferably 50,000 or less since developability is good.

The weight average molecular weight (Mw) is a value measured by gel permeation chromatography (GPC) (for example, “HLC-8220GPC” manufactured by Tosoh Corporation).

### <Thermal Curing Agent>

The thermal curing agent used in the present embodiment is not particularly limited, and a publicly known thermal curing agent in the related art can be used. Examples of the thermal curing agent include an epoxy resin, a carbodiimide resin, and an amino resin.

Examples of the epoxy resin include bisphenol type epoxy resins such as a bisphenol A type epoxy resin, a modified derivative of the bisphenol A type epoxy resin, a bisphenol F type epoxy resin, and a bisphenol S type epoxy resin; novolac type epoxy resins such as a phenol novolac type epoxy resin and a cresol novolac type epoxy resin; modified derivatives of the novolac type epoxy resins; biphenyl type epoxy resins; epoxy resins containing naphthalene ring; an alicyclic epoxy resin, an epoxy resin having a triazine skeleton, and a dicyclopentadiene type epoxy resin. The bisphenol type epoxy resins and the modified derivatives of the bisphenol type epoxy resins are preferable in view of adhesion. The novolac type epoxy resins, the modified derivatives of the novolac type epoxy resins, and alicyclic epoxy are preferable in view of heat resistance.

Examples of the carbodiimide resin include a polycarbodiimide resin, a block carbodiimide resin in which a carbodiimide group in a carbodiimide compound is blocked with an amino group that can be released by heating, and a cyclic carbodiimide resin. The block carbodiimide resin is preferable in view of storage stability.

Examples of the amino resin include a melamine resin and a benzoguanamine resin.

Among the above, the thermal curing agent is preferably an epoxy resin and a carbodiimide resin in view of heat resistance and insulation properties.

An amount to use the thermal curing agent is preferably 0.9 to 1.3 equivalents to the carboxyl group of the (meth)acrylic photocurable polymer. When the thermal curing agent is 0.9 equivalent or more with respect to the carboxyl group of the (meth)acrylic photocurable polymer, the (meth)acrylic photocurable polymer can be sufficiently cured. When the thermal curing agent is 1.3 equivalents or less, the excess thermal curing agent not involved in curing is difficult to remain.

### <Photopolymerization Initiator>

The photopolymerization initiator is a component that promotes a curing reaction by irradiation with energy rays. Examples of the energy rays include visible light, ultraviolet rays, x-rays, and electron rays. The ultraviolet rays are preferably used in the present embodiment.

The photopolymerization initiator is not particularly limited, and any photopolymerization initiator such as an acylphosphine oxide-based photopolymerization initiator, an alkylphenone-based photopolymerization initiator, an intramolecular hydrogen abstraction type photopolymerization initiator, or the like can be used. Among them, the acylphosphine oxide-based photopolymerization initiator and the alkylphenone-based photopolymerization initiator are preferable in view of reactivity and curing uniformity. Specifically, examples of the acylphosphine oxide-based photopolymerization initiator include 2,4,6-trimethyl benzoyl phenyl phosphine oxide, 2,2-dimethoxy-1,2-diphenylethane-1-one, and phenyl glyoxylic acid methyl ester. Examples of the alkylphenone-based photopolymerization initiator include 2-methyl-1-[4-(methyl thio)phenyl]-2-morpholinopropane-1-one and 2-benzyl-2-dimethyl amino-1-(4-morpholino phenyl)-butanone-1. Among them, 2,4,6-trimethyl benzoyl phenyl phosphine oxide is preferable in view of high radical generation efficiency and deep curability.

The content of the photopolymerization initiator is preferably 2 to 20 parts by mass, more preferably 6 to 14 parts by mass with respect to 100 parts by mass of the (meth)acrylic photocurable polymer. When the content of the photopolymerization initiator is 2 parts by mass or more with respect to 100 parts by mass of the (meth)acrylic photocurable polymer, curing reactivity tends to be good and long term reliability tends to improve. When the content of the photopolymerization initiator is 20 parts by mass or less, weakness of the cured film is not caused, and adhesion to the circuit board is not impaired.

A desired additive can be added to the resin composition for resists of the present invention without impairing the effects of the present invention. Examples of the additive include a photopolymerizable compound other than the (meth)acrylic photocurable polymer, a colorant, a filler, a flame retardant, a dispersant, a surface conditioner (leveling agent, antifoaming agent), and other resins.

<Photopolymerizable Compound of Present Invention Other than (Meth)Acrylic Photocurable Polymer>

An example of the photopolymerizable compound of the present invention used in the present embodiment other than the (meth)acrylic photocurable polymer is not particularly limited as long as it can cause a crosslinking reaction by light, but a monomer or polymer having an ethylenically unsaturated bond in the molecule is preferably used in view of versatility.

Examples of the monomer having an ethylenically unsaturated bond in the molecule include a (meth)acrylate compound, a bisphenol A-based di(meth)acrylate compound, an epoxy acrylate compound, a modified epoxy acrylate compound, a fatty acid modified epoxy acrylate compound, an amine-modified bisphenol A-based epoxy acrylate compound, a hydrogenated bisphenol A-based di(meth)acrylate compound, a di(meth)acrylate compound having a urethane bond in the molecule, a (meth)acrylate compound having a hydrophobic skeleton in the molecule, a polyalkylene glycol di(meth)acrylate compound having both a (poly)oxyethylene chain and a (poly)oxypropylene chain in the molecule, a trimethylolpropane di(meth)acrylate compound, and a polyester acrylate compound. One of these can be used alone, or two or more of these can be used in combination.

Examples of the monomer having an ethylenically unsaturated bond in the molecule that is preferably used in the present embodiment include “EBECRYL-3708”, “EBECRYL-1039”, and “EBECRYL-230” (all trade names, manufactured by DAICEL-ALLNEX LTD.) as commercially available monomers.

The content of the photopolymerizable compound is preferably 10 to 60 parts by mass, more preferably 20 to 50 parts by mass with respect to 100 parts by mass of the (meth)acrylic photocurable polymer. When the content of the photopolymerizable compound is 10 parts by mass or more with respect to 100 parts by mass of the (meth)acrylic photocurable polymer, it is possible to improve resolution when the circuit board is produced, so that a fine circuit pattern can be drawn. When the content of the photopolymerizable compound is 60 parts by mass or less, the cured film preferably has flame retardancy and heat resistance.

Examples of the polymer having an ethylenically unsaturated bond in the molecule include an acid modified polyether-based urethane acrylate, an acid modified polycarbonate-based urethane acrylate, an acid modified polyester-based urethane acrylate, an acid modified epoxy acrylate, and an acrylic acrylate containing an acid group. One of these can be used alone, or two or more of these can be used in combination.

The content of the polymer having an ethylenically unsaturated bond in the molecule is preferably less than 100 parts by mass, and more preferably less than 80 parts by mass with respect to 100 parts by mass of the (meth)acrylic photocurable polymer. When the content of the polymer having an ethylenically unsaturated bond in the molecule is less than 100 parts by mass with respect to 100 parts by mass of the (meth)acrylic photocurable polymer, it is preferable that the cured film is not warped and chemical resistance is not impaired.

### (Colorant)

The colorant used in the present embodiment includes an organic pigment and an inorganic pigment.

Examples of the organic pigment include organic pigments based on isoindoline, phthalocyanine, quinacridone, benzimidazolone, dioxazine, indanthrene, perylene, azo, quinophthalone, anthraquinone, aniline, and cyanine.

Examples of the inorganic pigment include carbon black, titanium black, ultramarine blue, Prussian blue, lead yellow, zinc yellow, red lead, red iron oxide, zinc white, lead white, lithopone, and titanium dioxide.

One of these may be used alone, or two or more of these may be used in combination. Among them, the organic pigment is preferably used in view of color resistance and insulation properties.

The colorant is preferably used in a dispersion liquid. The dispersion liquid can be prepared by adding a composition obtained by mixing the colorant and a dispersant in advance to an organic solvent (or vehicle) and dispersing them. The vehicle refers to part of a medium in which a pigment is dispersed when a coating material is in a liquid state, and contains a part (binder) that is liquid and combines with the pigment to harden a coating film, and a component (organic solvent) that dissolves and dilutes the binder.

The colorant used in the present embodiment preferably has a number average particle diameter of 0.001 μm to 0.1 μm, and more preferably 0.01 μm to 0.08 μm in view of dispersion stability. Here, the “particle diameter” refers to a diameter of a circle having the same area as an electron micrograph image of the particle. The “number average particle diameter” refers to an average value of the particle diameters of 100 particles, among the particle diameters determined above for a large number of particles.

The content of the colorant is preferably 0.1 to 5 parts by mass, more preferably 1 to 3 parts by mass with respect to 100 parts by mass of the (meth)acrylic photocurable polymer. When the content of the colorant is less than 0.1 part by mass, energy rays tend to be easily reflected from the circuit board at the time of patterning and a defect called halation tends to occur. When the content of the colorant is more than 5 parts by mass, exposure light does not reach the bottom of the film at the time of photocuring, an uncured portion may occur inside the film, and the pattern formation may become poor (resolution may be poor) due to erosion of the cured film during etching. Therefore, the content of the colorant is preferably in the above range.

### (Filler)

Examples of the filler used in the present embodiment include: ceramic fine particles such as alumina, cordierite, and zircon; and filler components such as barium sulfate, talc, silica, titanium oxide, aluminum oxide, and calcium carbonate.

The content of the filler is preferably 20 to 200 parts by mass, more preferably 50 to 150 parts by mass with respect to 100 parts by mass of the (meth)acrylic photocurable polymer. When the content of the filler is in the above range, it does not easily affect the resolution.

### (Flame Retardant)

Examples of the flame retardant used in the present embodiment include a phosphorus flame retardant and a metal hydroxide, and among them, the phosphorus flame retardant is preferable in view of flame retardancy. The phosphorus flame retardant is a compound containing at least one phosphorus element in the molecule. The phosphorus flame retardant is not limited, but examples of the phosphorous flame retardant include red phosphorus, a condensed phosphate ester compound, a cyclic organic phosphorus compound, a phosphazene compound, a (meth)acrylate-based compound containing a phosphorus, a epoxy-based compound containing a phosphorus, and a polyol-based compound containing a phosphorus, and an amine-based compound containing a phosphorus, ammonium polyphosphate, melamine phosphate, and a phosphinic acid metal salt. One of these may be used alone, or two or more of these may be used in combination.

The content of the flame retardant is preferably 20 to 60 parts by mass, more preferably 30 to 50 parts by mass with respect to 100 parts by mass of the (meth)acrylic photocurable polymer. When the content of the flame retardant is in the above range, flame retardancy can be exhibited but other properties are not influenced.

### (Dispersant)

Examples of the dispersant include epoxysilane, (meth)acrylic silane, and a wetting dispersant.

### (Surface Conditioner)

Examples of the surface conditioner include a silicone resin-based additive, a fluorine resin-based additive, and a commercially available surfactant.

The photocurable resin composition of the present embodiment can be produced in accordance with a method publicly known in the related art, but is not particularly limited. For example, the photocurable resin composition can be produced by sequentially mixing the photopolymerization initiator, the thermal curing agent, and other optional components in the (meth)acrylic photocurable polymer. In a mixing step of mixing the filler, the flame retardant, or the like, mixing can be performed by using a mixer such as a bead mill or a roll mill.

### <Cured Product>

The resin composition for resists of the present invention can be cured by irradiation with energy rays to obtain a cured product (cured film) having a desired thickness.

When the resin composition for resists is cured, the resin composition for resists is formed into a desired shape, specifically, the resin composition for resists is applied to a surface of a base material or the like to a predetermined dry thickness to form a resin layer, and the resin composition is dried and then irradiated with energy rays to perform curing. The energy rays are not particularly limited, active energy rays such as visible light rays, ultraviolet rays, X-rays, and electron rays can be used. Ultraviolet rays are preferably used in view that a curing reaction can be efficiently performed.

A light source from which ultraviolet rays (UV) are emitted can be used as a light source of ultraviolet rays. Examples of the light source of ultraviolet rays include a metal halide lamp, a high pressure mercury lamp, a xenon lamp, a mercury xenon lamp, a halogen lamp, a pulse xenon lamp, and a light emitting diode (LED).

The cured product obtained by curing the resin composition for resists of the present invention preferably has a glass transition temperature (Tg) of 100° C. or lower. When the glass transition temperature of the cured product is 100° C. or lower, warpage can be reduced. The glass transition temperature is preferably 90° C. or lower, more preferably 80° C. or lower. A lower limit thereof is not particularly limited, but the cured product may have strong tack (stickiness) and may be difficult to handle when the glass transition temperature is too low. Therefore, the glass transition temperature is preferably 40° C. or higher, and more preferably 50° C. or higher.

The glass transition temperature (Tg) can be measured using dynamic viscoelasticity measurement (DMA) (for example, “RSA-G2” (trade name) manufactured by TA Instruments Japan Inc.).

A thickness of the cured film can be, for example, 5 μm to 100 μm, preferably 10 μm to 50 μm for use as an electronic device material such as an image display device.

### <Other Uses>

Examples of a preferable use of the resin composition for resists other than the electronic device material include solder resist ink and a solder resist film. The resin composition for resists of the present invention can be suitably used as a solder resist film used for a circuit board or a substrate for a semiconductor package.

### (Solder Resist Film)

The solder resist film of the present invention includes a support and a photocurable resin composition layer for resists formed on the support. The resin composition layer for resists contains the resin composition for resists of the present embodiment. The solder resist film may have a protective film layer on a face, opposite to the support, of the resin composition layer for resists.

Hereinafter, a method for producing the solder resist film will be described.

The resin composition for resists of the present embodiment is dissolved in solvent such as methanol, ethanol, acetone, methyl ethyl ketone, methyl cellosolve, ethyl cellosolve, toluene, N,N-dimethylformamide, and propylene glycol monomethyl ether, or a mixed solvent thereof to obtain a solution having a solid content of about 30 mass % to 70 mass %, and then the solution is applied on the support to preferably form the resin composition layer for resists.

Examples of the support include a polyester such as polyethylene terephthalate, and a polymer film having heat resistance and solvent resistance such as polypropylene and polyethylene. A face of the support on which the resin composition is applied is preferably subjected to a mold release treatment.

A thickness of the support can be appropriately selected by the uses and a thickness of the resin composition layer for resists.

The thickness of the resin composition layer for resists varies depending on the uses, but is preferably 5 μm to 100 μm, and more preferably 10 μm to 50 μm in a thickness after drying in which the solvent is removed by heating and/or hot air blowing.

Examples of the protective film include a polyethylene film, a polypropylene film, and polyethylene terephthalate.

The solder resist film of the present invention can be used for circuit protection of a flexible printed wiring board, or an interlayer adhesive and circuit protection of the substrate for a semiconductor package.

The resist pattern can be manufactured by, for example, a manufacturing method including: a lamination step of laminating the solder resist film on a substrate for forming a circuit: an exposure step of irradiating a predetermined part of the resin composition layer for resists of the solder resist film with active rays to form a cured portion in the resin composition layer for resists; a developing step of removing the resin composition layer for resists other than the cured portion; and a thermosetting step of curing the resin composition layer for resists of the cured portion by heating.

When the solder resist film has a protective film, the manufacturing method further includes a step of removing the protective film from the solder resist film before the lamination step.

The substrate for forming a circuit includes an insulating layer, and a conductor layer (a layer made of conductive materials such as copper, copper-based alloys, silver, silver-based alloys, nickel, chromium, iron, and iron-based alloys such as stainless steel, preferably made of copper or copper-based alloys) formed on the insulating layer by an etching method or a printing method. The resin composition layer for resists of the solder resist film is laminated to be located on the conductor layer side of the substrate for forming a circuit in the lamination step.

Examples of a method of laminating the solder resist film in the lamination step include a method of laminating by crimping the substrate for forming a circuit while heating the resin composition layer for resists. In a case of lamination in this manner, the resin composition layer for resists is preferably laminated under reduced pressure in view of adhesion, trackability, and the like.

In the lamination step, the photocurable resin composition layer is preferably heated at a temperature of 30° C. or higher and lower than 80° C., a crimping pressure is preferably about 0.1 MPa to 2.0 MPa, and an ambient atmospheric pressure is preferably 3 hPa or lower.

In the exposure step, a predetermined part of the resin composition layer for resists is irradiated with active rays to form a cured portion. Examples of a method for forming the cured portion include a method of irradiation with the active rays in an image form via a negative or positive mask pattern called an artwork. Further, exposure by a direct drawing method such as an LDI method and a digital light processing (DLP) exposure method is also possible which do not use a mask pattern. In this case, when the support present on the resin composition layer for resists is transparent, the resin composition layer for resists can be directly irradiated with the active rays. When the support is not transparent, the support is removed, and then the resin composition layer for resists is irradiated with the active rays.

As a light source of the active rays, a publicly known light source, for example, a light source that effectively radiates ultraviolet rays such as a carbon arc lamp, a mercury vapor arc lamp, an extra-high pressure mercury lamp, a high pressure mercury lamp, a xenon lamp, or a semiconductor laser can be used. Further, a light source that effectively radiates visible light such as a photographic flood electric bulb or a solar lamp can be used.

Next, when the support is present on the resin composition layer for resists, the support is removed, and then the photocurable resin composition layer other than the curing portion is removed and developed by wet development, dry development, or the like in the development step to form the resist pattern.

In a case of wet development, the resin composition layer for resists can be developed by a publicly known method such as spraying, swinging immersion, brushing, and scratching using a developer such as an aqueous alkaline solution. A developer that is safe and stable and has good operability is preferable. For example, a dilute solution of sodium carbonate (1 mass % to 5 mass % aqueous solution) at 20° C. to 50° C. is used as the developer.

When the resist pattern obtained by the above forming method is used as, for example, a solder resist film of a printed wiring board, the thermosetting step is performed after the development step.

Examples of a heating method can include heating by an oven. The heating is preferably performed at a temperature of 80° C. or higher for 20 to 120 minutes as heating conditions.

### (Printed Wiring Board)

According to the above method, the printed wiring board (including a substrate for a semiconductor package and a flexible printed wiring board) is obtained in which a wiring pattern including conductive materials and the solder resist film are formed in this order on the insulating layer.

### (Electronic Device)

The electronic device of the present invention includes a circuit board or a substrate for a semiconductor package including the above-described solder resist film.

### EXAMPLES

Hereinafter, the present invention will be described in detail with Examples and Comparative Examples, but the present invention is not limited thereto. In the examples, “part” and “%” are on a mass basis.

### Synthesis Example 1: Synthesis of (Meth)Acrylic Photocurable Polymer (A)

20.6 parts of acrylic acid, 9.0 parts of styrene, 37.4 parts of butyl acrylate, 10 parts of isostearyl acrylate, 80 parts of 1-methoxy-2-propanol, and 3.0 parts of 2,2-azobisisobutyronitrile (hereinafter, AIBN) were mixed in a flask equipped with a stirrer, a dropping funnel, a cooling tube, and a thermometer, and the mixture was stirred at 110° C. for 7 hours in a nitrogen atmosphere. Then, 23.0 parts of glycidyl methacrylate (hereinafter, GMA), 0.04 part of methoquinone, and 0.24 part of triphenyl phosphine (hereinafter, TPP) were mixed under the atmosphere (oxygen concentration of 7% or more), and then stirred at 100° C. A reaction was terminated at a time point when the acid value reached 90 mg KOH/g (15 hours) by a neutralization titration method using potassium hydroxide. Subsequently, the reactant was cooled and 1-methoxy-2-propanol was added to the reactant so that the nonvolatile components were 40%.

A weight average molecular weight of the obtained (meth)acrylic photocurable polymer (A) (acrylic acrylate containing an acid group copolymerized with an isostearyl acrylate) was measured by gel permeation chromatography (GPC) (standard substance: polyethylene glycol and polyethylene oxide) to be 23,000. A content of isostearyl acrylate (hereinafter, ISTA) was 10% as a content of a segment derived from ISTA, a theoretical value of the glass transition temperature (theoretical Tg) was 0° C., a theoretical value of a double bond equivalent was 610 g/eq, and a carboxyl group equivalent calculated from the acid value was 622 g/eq.

### Synthesis Example 2: Synthesis of (Meth)Acrylic Photocurable Polymer (B)

A (meth)acrylic photocurable polymer (B) (acrylic acrylate containing an acid group copolymerized with an isostearyl acrylate) was obtained in the same manner as in Synthesis Example 1, except that charge amounts of the raw materials were 0.1 part of styrene, 36.4 parts of butyl acrylate, and 20 parts of isostearyl acrylate. A weight average molecular weight (Mw) of the (meth)acrylic photocurable polymer (B) was 23,000, the content of the segment derived from ISTA was 20%, the theoretical value of the glass transition temperature (theoretical Tg) was −7.5° C., the theoretical value of the double bond equivalent was 610 g/eq, and the carboxyl group equivalent calculated from the acid value was 622 g/eq.

### Synthesis Example 3: Synthesis of (Meth)Acrylic Photocurable Polymer (C)

A (meth)acrylic photocurable polymer (C) (acrylic acrylate containing an acid group copolymerized with an isostearyl acrylate) was obtained in the same manner as in Synthesis Example 1, except that charge amounts of the raw materials were 9.4 parts of styrene, 27.0 parts of butyl acrylate, and 20 parts of isostearyl acrylate. A weight average molecular weight (Mw) of the (meth)acrylic photocurable polymer (C) was 21,500, the content of the segment derived from ISTA was 20%, the theoretical value of the glass transition temperature (theoretical Tg) was 5.8° C., the theoretical value of the double bond equivalent was 610 g/eq, and the carboxyl group equivalent calculated from the acid value was 622 g/eq.

### Synthesis Example 4: Synthesis of (Meth)Acrylic Photocurable Polymer (D)

A (meth)acrylic photocurable polymer (D) (acrylic acrylate containing an acid group copolymerized with an isostearyl acrylate) was obtained in the same manner as in Synthesis Example 1, except that charge amounts of the raw materials were 0.1 part of styrene, 10.3 parts of butyl acrylate, and 46 parts of isostearyl acrylate. A weight average molecular weight (Mw) of the (meth)acrylic photocurable polymer (D) was 25,000, the content of the segment derived from ISTA was 46%, the theoretical value of the glass transition temperature (theoretical Tg) was 5.0° C., the theoretical value of the double bond equivalent was 610 g/eq, and the carboxyl group equivalent calculated from the acid value was 622 g/eq.

### Synthesis Example 5: Synthesis of (Meth)Acrylic Photocurable Polymer (E)

A (meth)acrylic photocurable polymer (E) (acrylic acrylate containing acid group copolymerized with isostearyl acrylate) was obtained in the same manner as in Synthesis Example 1, except that charge amounts of the raw materials were 21.0 parts of styrene and 25.4 parts of butyl acrylate.

A weight average molecular weight (Mw) of the (meth)acrylic photocurable polymer (E) was 27,000, the content of the segment derived from ISTA was 10%, the theoretical value of the glass transition temperature (theoretical Tg) was 18.0° C., the theoretical value of the double bond equivalent was 610 g/eq, and the carboxyl group equivalent calculated from the acid value was 622 g/eq.

### (i) Production of Photosensitive Resin Composition (Resin Composition for Resists)

Components were combined at a combination ratio shown in Table 1 and mixed with a mixer to obtain photocurable resin compositions used in Examples 1 to 8 and Comparative Examples 1 to 3.

### (ii) Production of Dry Film

The photosensitive resin composition obtained in the above (i) was applied onto a polyethylene terephthalate (PET) film (PET film for support) having a thickness of 25 μm so that a thickness of the photosensitive resin composition after drying was 25 μm, and dried at 80° C. for 5 minutes, and then a polyethylene film was attached on a face side where the photosensitive resin composition was applied to obtain a dry film.

### 1. Measurement of Glass Transition Temperature (Tg)

### (1) Production of Test Film

The polyethylene film was peeled off from the dry film produced in the above (ii). Then a polyethylene terephthalate (PET) film (PET film for peeling) having a thickness of 38 μm, on which releasing treatment was performed, was attached on the photosensitive resin composition layer side of the photosensitive resin film including the PET film for support and the photosensitive resin composition layer by vacuum lamination (“MVLP-500/600-II” (device name) manufactured by Meiki Co., Ltd.). The vacuum lamination was carried out at a hot plate temperature of 50° C. to 70° C., under a pressing pressure of 0.5 MPa to 1.0 MPa, for pressing time of 10 to 20 seconds, and a vacuum degree of 3 hPa or less. After the vacuum lamination, an extra-high pressure mercury lamp irradiated the dry film with ultraviolet rays of 100 mJ/cm² from a side of the PET film for peeling. After the irradiation, the PET film for peeling was peeled off, and the photosensitive resin composition layer was sprayed with a 1 wt % aqueous sodium carbonate solution of 30° C. at a spray pressure of 0.18 MPa and developed for 60 seconds. After the development, the photosensitive resin composition layer was irradiated with ultraviolet rays of 1,000 mJ/cm² with a high pressure mercury lamp. After the irradiation, the dry film was cured at 180° C. for 120 minutes with a hot air circulating drier. After the curing, the PET film for support was peeled off to obtain the test film.

### (2) Measurement Method

Dynamic viscoelasticity measurement (DMA) (“RSA-G2” (device name) manufactured by TA Instruments Japan Inc.) was used to measure the glass transition temperature (Tg) of the test film. The results are shows in Table 1.

### 2. Evaluation of Chemical Resistance (Flux Resistance)

### (1) Production of Test Specimen

The polyethylene film was peeled off from the dry film produced in the above (ii), and electrolytic copper foil of 35 μm treated with a chemical liquid CZ manufactured by MEC COMPANY LTD. was attached on the photosensitive resin composition layer of the photosensitive resin film including the PET film for support and the photosensitive resin composition layer by vacuum lamination (“MVLP-500/600-II” (device name) manufactured by Meiki Co., Ltd.). Vacuum lamination was carried out at a hot plate temperature of 50° C. to 70° C., a pressing pressure of 0.5 MPa to 1.0 MPa, pressing time of 10 to 20 seconds, and a vacuum degree of 3 hPa or less. After the vacuum lamination, an extra-high pressure mercury lamp irradiated the dry film with ultraviolet rays of 100 mJ/cm² from a side of the PET film for support. After the irradiation, the PET film for support was peeled off, and the photosensitive resin composition layer was sprayed with a 1 wt % aqueous sodium carbonate solution of 30° C. at a spray pressure of 0.18 MPa and developed for 60 seconds. After the development, a high pressure mercury lamp irradiated the dry film with the ultraviolet rays of 1,000 mJ/cm². After the irradiation, the dry film was cured at 180° C. for 120 minutes with a hot air circulating drier to obtain the test specimen.

### (2) Test Method

A flux (part number: Sparkle flux WF-6317) manufactured by Senju Metal Industry Co., Ltd. was measured to be 0.1 g per unit area (25 cm²) on an entire surface of the photosensitive resin composition layer side of the test specimen, and was uniformly applied to the entire surface of the photosensitive resin composition layer side of the test specimen. After the application, the test specimen passed through a conveyor reflow furnace set to conditions under which an object temperature can be maintained at 260° C. for 20 seconds. After that, the test specimen was naturally cooled at room temperature and washed with running water to remove the flux. After water on the surface was wiped with a dry cloth, the surface of the photosensitive resin composition layer side of the test specimen was wiped with a waste cloth soaked with ethanol, and it was visually confirmed whether a resist adhered to the waste cloth. A test specimen in which no resist adhered to the waste cloth was evaluated as “A (chemical resistance)” and a test specimen in which a resist adhered to the waste cloth was evaluated as “C (no chemical resistance)”. The results are shows in Table 1.

### 3. Evaluation of Warpage

### (1) Production of Test Specimen

The polyethylene film was peeled off from the dry film produced in the above (ii), and electrolytic copper foil of 12 μm was attached on the photosensitive resin composition layer of the photosensitive resin film including the PET film for support and the photosensitive resin composition layer by vacuum lamination (“MVLP-500/600-II” (device name) manufactured by Meiki Co., Ltd.). Vacuum lamination was carried out at a hot plate temperature of 50° C. to 70° C., a pressing pressure of 0.5 MPa to 1.0 MPa, pressing time of 10 to 20 seconds, and a vacuum degree of 3 hPa or less. After the vacuum lamination, an extra-high pressure mercury lamp irradiated the dry film with ultraviolet rays of 100 mJ/cm² from a side of the PET film for support. After the irradiation, the PET film for support was peeled off, and the photosensitive resin composition layer was sprayed with a 1 wt % aqueous sodium carbonate solution of 30° C. at a spray pressure of 0.18 MPa and developed for 60 seconds. After the development, the photosensitive resin composition layer was irradiated with ultraviolet rays of 1,000 mJ/cm² with a high pressure mercury lamp. After the irradiation, the dry film was cured at 180° C. for 120 minutes with a hot air circulating drier to obtain the test specimen.

### (2) Test Method

The test specimen was disposed and placed on a table of a test chamber set to a temperature of 23° C. and humidity of 50% with the photosensitive resin composition layer side facing upward. After 24 hours, a state of the test specimen was observed and evaluated according to the following criteria. The results are shows in Table 1.

[Evaluation Criteria]

A (good): an end of the test specimen was not away from the table at all.

B (fair): an end of the test specimen was away from the table. A separation distance is less than 10 mm, which has no problem in practical use.

C (bad): an end of the test specimen was away from the table. A separation distance is 10 mm or more, which has a problem in practical use.

TABLE 1

| | | | | | | | | | | Compar- | Compar- | Compar- |
|---|---|---|---|---|---|---|---|---|---|---|---|---|
| | | | | | | | | | | ative | ative | ative |
| | | Exam- | Exam- | Exam- | Exam- | Exam- | Exam- | Exam- | Exam- | Exam- | Exam- | Exam- |
| | | ple 1 | ple 2 | ple 3 | ple 4 | ple 5 | ple 6 | ple 7 | ple 8 | ple 1 | ple 2 | ple 3 |
| Compo- | (Meth)acrylic | 100 | 100 | 100 | 100 | — | — | — | — | — | — | — |
| sition | photocurable | | | | | | | | | | | |
| | polymer (A) | | | | | | | | | | | |
| | (Meth)acrylic | — | — | — | — | 100 | — | — | — | — | — | — |
| | photocurable | | | | | | | | | | | |
| | polymer (B) | | | | | | | | | | | |
| | (Meth)acrylic | — | — | — | — | — | 100 | — | — | — | — | — |
| | photocurable | | | | | | | | | | | |
| | polymer (C) | | | | | | | | | | | |
| | (Meth)acrylic | — | — | — | — | — | — | 100 | — | — | — | — |
| | photocurable | | | | | | | | | | | |
| | polymer (D) | | | | | | | | | | | |
| | (Meth)acrylic | — | — | — | — | — | — | — | 100 | — | — | — |
| | photocurable | | | | | | | | | | | |
| | polymer (E) | | | | | | | | | | | |
| | (Meth)acrylic | — | — | — | — | — | — | — | — | 100 | — | — |
| | photocurable | | | | | | | | | | | |
| | polymer (F) | | | | | | | | | | | |
| | Acid modi- | — | — | — | — | — | — | — | — | — | 100 | — |
| | fied epoxy | | | | | | | | | | | |
| | acrylate (G) | | | | | | | | | | | |
| | Acid modified | — | — | — | — | — | — | — | — | — | — | 100 |
| | urethane | | | | | | | | | | | |
| | acrylate (H) | | | | | | | | | | | |
| | Modified | 40 | 40 | 40 | 40 | 40 | 40 | 40 | 40 | 40 | 40 | 40 |
| | epoxy | | | | | | | | | | | |
| | acrylate (I) | | | | | | | | | | | |
| | Thermal curing | — | — | 70 | — | — | — | — | — | — | — | — |
| | agent (J) | | | | | | | | | | | |
| | Thermal curing | 77 | 77 | — | 77 | 77 | 77 | 77 | 77 | 59 | 83 | 42 |
| | agent (K) | | | | | | | | | | | |
| Compo- | Photopoly- | 10 | 10 | 10 | 10 | 10 | 10 | 10 | 10 | 10 | 10 | 10 |
| sition | merization | | | | | | | | | | | |
| | initiator (L) | | | | | | | | | | | |
| | Filler (M) | 50 | 50 | 50 | — | 50 | 50 | 50 | 50 | 50 | 50 | 50 |
| | Flame | — | — | — | 50 | — | — | — | — | — | — | — |
| | retardant (N) | | | | | | | | | | | |
| | Colorant (O) | — | 1 | — | — | — | — | — | — | — | — | — |
| | Glass | 0 | 0 | 0 | 0 | −7.5 | 5.8 | 5.0 | 18 | 136 | 65 | Unknown |
| | transition | | | | | | | | | | | |
| | temperature | | | | | | | | | | | |
| | (theoretical | | | | | | | | | | | |
| | Tg) of photo- | | | | | | | | | | | |
| | curable | | | | | | | | | | | |
| | polymer (° C.) | | | | | | | | | | | |
| | Double bond | 610 | 610 | 610 | 610 | 610 | 610 | 610 | 610 | 380 | 500 | 700 |
| | equivalent in | | | | | | | | | | | |
| | photocurable | | | | | | | | | | | |
| | polymer (g/eq) | | | | | | | | | | | |
| | Carboxyl group | 622 | 622 | 622 | 622 | 622 | 622 | 622 | 622 | 812 | 571 | 1120 |
| | equivalent in | | | | | | | | | | | |
| | photocurable | | | | | | | | | | | |
| | polymer (g/eq) | | | | | | | | | | | |
| | Glass | 70 | 70 | 75 | 70 | 60 | 75 | 60 | 80 | 130 | 75 | 70 |
| | transition | | | | | | | | | | | |
| | temperature | | | | | | | | | | | |
| | Tg of test | | | | | | | | | | | |
| | film (° C.) | | | | | | | | | | | |
| Evalu- | Chemical | A | A | A | A | A | A | A | A | A | A | C |
| ation | resistance | | | | | | | | | | | |
| | (flux resis- | | | | | | | | | | | |
| | tance) | | | | | | | | | | | |
| | Warpage | A | A | A | A | A | A | A | B | C | C | A |

Note)
(A): Acrylic acrylate containing acid group copolymerized with isostearyl acrylate (1): Mw = 23,000, acid value = 90 mg KOH/g, ISTA proportion of 10%
(B): Acrylic acrylate containing acid group copolymerized with isostearyl acrylate (2): Mw = 23,000, acid value = 90 mg KOH/g, ISTA proportion of 20%
(C): Acrylic acrylate containing acid group copolymerized with isostearyl acrylate (3): Mw = 21,500, acid value = 90 mg KOH/g, ISTA proportion of 20%
(D): Acrylic acrylate containing acid group copolymerized with isostearyl acrylate (4): Mw = 25,000, acid value = 90 mg KOH/g, ISTA proportion of 46%
(E): Acrylic acrylate containing acid group copolymerized with isostearyl acrylate (5): Mw = 27,000, acid value = 90 mg KOH/g, ISTA proportion of 10%
(F): “(ACA)-Z250” (trade name) manufactured by DAICEL-ALLNEX LTD., acrylic acrylate containing acid group: Mw = 22,000, acid value of 69 mg KOH/g
(G): “ZFR-1491H” (trade name) manufactured by Nippon Kayaku Co., Ltd., carboxylic acid modified bisphenol F type epoxy acrylate, Mw = 11,000, acid value of 98 mg KOH/g
(H): Urethane acrylate containing ester bond and unsaturated bond in main chain, Mw = 10,000, acid value of 50 mg KOH/g
(I): “EBECRY-3708” (trade name) manufactured by DAICEL-ALLNEX LTD., Mw = 1,500, bifunctional
(J): “JER1001” (trade name) manufactured by Mitsubishi Chemical Corporation, bisphenol A type epoxy resin, epoxy equivalent of 475
(K): Castor oil diol-based polycarbodiimide blocked with dissociated amine of 110° C. (equivalent of 440 g/eq, bifunctional)
(L): 2,4,6-trimethyl benzoyl diphenyl phosphine oxide
(M): “SC2050-MB” (trade name) manufactured by Admatechs Co., Ltd., silica having average particle diameter of 0.5 μm
(N): Phosphinic acid metal salt
(O): Isoindoline (yellow pigment)

From the results of Table 1, any of Examples 1 to 8 had chemical resistance and can reduce warpage. Particularly Examples 1 to 7 were excellent without any warpage in the test specimen. In contrast, warpage cannot be reduced in Comparative Examples 1 to 2. Comparative Example 3 had insufficient chemical resistance. From these results, it was found that the resin composition for resists of the present invention can achieve both chemical resistance and reduction of warpage.

Although the present invention has been described in detail and with reference to particular embodiments, it will be apparent to those skilled in the art that various changes and modifications can be made without departing from the spirit and scope of the present invention. This application is based on Japanese Patent Application No. 2018-145361 filed on Aug. 1, 2018, the contents of which are incorporated herein by reference.

1. A resin composition for resists comprising:
a (meth)acrylic photocurable polymer;
a thermal curing agent; and
a photopolymerization initiator,
wherein
the (meth)acrylic photocurable polymer comprises
a carboxyl group,
a chain aliphatic hydrocarbon group having 12 or more carbon atoms, and
an unsaturated double bond, and
the (meth)acrylic photocurable polymer has a glass transition temperature (Tg) of 20° C. or lower.

2. The resin composition for resists according to claim 1,
wherein the (meth)acrylic photocurable polymer is an addition copolymer obtained by reacting
a reactive compound containing an ethylenically unsaturated double bond with
a (meth)acrylic copolymer obtained by copolymerizing at least
a (meth)acrylic polymerizable compound containing a carboxyl group and
a polymerizable compound containing a chain aliphatic hydrocarbon group.

3. The resin composition for resists according to claim 2,
wherein the polymerizable compound containing a chain aliphatic hydrocarbon group is an alkyl (meth)acrylate having 12 to 24 carbon atoms.

4. The resin composition for resists according to claim 2,
wherein a content of a segment derived from the polymerizable compound containing a chain aliphatic hydrocarbon group in the (meth)acrylic photocurable polymer is in a range of 10 mass % to 50 mass %.

5. The resin composition for resists according to claim 1,
wherein the (meth)acrylic photocurable polymer has an acid value of 50 mg KOH/g to 100 mg KOH/g.

6. The resin composition for resists according to claim 1,
wherein the (meth)acrylic photocurable polymer has a double bond equivalent of 300 g/eq to 1000 g/eq.

7. The resin composition for resists according to claim 1,
wherein a cured product obtained by curing the resin composition for resists has a glass transition temperature (Tg) of 100° C. or lower.

8. The resin composition for resists according to claim 1, further comprising
a photopolymerizable compound other than the (meth)acrylic photocurable polymer.

9. The resin composition for resists according to claim 1, that is for a solder resist.

10. The resin composition for resists according to claim 1, that is for a semiconductor package.

11. A cured product obtained by curing the resin composition for resists according to claim 1.

12. A solder resist film containing the resin composition for resists according to claim 1.

13. A circuit board containing the solder resist film according to claim 12.

14. A substrate for a semiconductor package containing the solder resist film according to claim 12.

15. An electronic device containing the circuit board according to claim 13.

16. An electronic device containing the substrate for a semiconductor package according to claim 14.
